(19) United States
(12) Patent Application Publication
(10) Pub. No.: US 2009/0315092 A1
(43) Pub. Date: Dec. 24, 2009

(54) SEMICONDUCTOR DEVICE AND MANUFACTURING METHOD THEREOF

(75) Inventor: Noriaki MIKASA, Tokyo (JP)

Correspondence Address: MCDERMOTT WILL & EMERY LLP, 600 13TH STREET, N.W., WASHINGTON, DC, 20005-3096, US

(73) Assignee: ELPIDA MEMORY, INC.

(21) Appl. No.: 12/482,146

(22) Filed: Jun. 10, 2009

(30) Foreign Application Priority Data
Jun. 20, 2008 (JP) 2008-161986

(51) Int. Cl. H01L 27/108; H01L 21/8242

(52) U.S. Cl. 257/303; 438/155; 257/E27.084; 257/E21.649

(57) ABSTRACT

A semiconductor device provided with a field-effect transistor, the field-effect transistor including: a active region defined by element isolating region 3 formed on semiconductor substrate 1; gate electrode 5 provided so as to intersect the active region and having at least a part thereof embedded in a gate trench formed on semiconductor substrate 1; and SOI structure channel layer 4 formed in the active region so that one lateral face thereof is opposite to a part of gate electrode 5 embedded in the gate trench and the other lateral face thereof is in contact with a lateral face of element isolating region 3, wherein impurity diffusion layer 5 that functions as a source/drain region is disposed above channel layer 4, and impurity diffusion layer 9 and channel layer 4 are formed spaced apart from each other.

This application is based upon and claims the benefit of priority from Japanese patent application No. 2008-161986, filed on Jun. 20, 2008, the disclosure of which is incorporated herein in its entirety by reference.

### BACKGROUND OF THE INVENTION

1. Field of the Invention

The present invention relates to a semiconductor device and a manufacturing method thereof and, in particular, to a semiconductor device including an RC transistor having an SOI structure and a manufacturing method thereof.

2. Description of the Related Art

In recent years, progress in miniaturization of semiconductor devices has necessitated reductions in the gate length of field-effect transistors (hereinafter described as transistors). A reduction in the gate length of a transistor brings the source and the drain of the transistor close to each other, thereby causing the effect of the drain to extend to the source. As a result, the threshold voltage of the transistor is problematically reduced. In consideration thereof, there is an increasing need for a high-performance transistor that suppresses a reduction in the threshold voltage while maximizing on-state current even when the gate length of the transistor is reduced. A technique for realizing such a high-performance transistor is disclosed in Japanese Patent Laid-Open No. 2007-158269. A deterioration in electrical properties that becomes apparent with a reduction in gate length, such as a drop in the threshold voltage of a transistor, is referred to as a short channel effect.

Japanese Patent Laid-Open No. 2007-158269 discloses a trench gate transistor having a channel layer provided at a lateral face portion of a gate electrode trench as a high-performance trench gate transistor for accommodating semiconductor device miniaturization. Consequently, the width of the channel layer can be increased so as to ensure that a sufficient on-state current flows even under a low gate voltage. In this case, a trench gate transistor refers to a transistor having a gate electrode embedded in a trench formed on a semiconductor substrate.

Hereinafter, a trench gate transistor provided with a channel layer at a lateral face portion of a gate electrode trench such as that described above will be referred to as an RC (recessed channel) transistor.

A technique for improving the electrical properties of an RC transistor by providing a channel layer of the transistor with an SOI (silicon on insulator) structure is disclosed in Japanese Patent Laid-Open No. 2007-258660.

An RC transistor having an SOI structure utilizing the technique disclosed in Japanese Patent Laid-Open No. 2007-258660 will be described below.

FIG. 1 is a plan view of an RC transistor having an SOI structure incorporating a technique for improving electrical properties. Depictions of an electrode extraction wiring layer and the like have been omitted.

The RC transistor having an SOI structure shown in FIG. 1 is defined by element isolating region 103 formed on a semiconductor substrate (not shown) made of silicon or the like, and is provided with diffusion layer region 101 formed by injecting an impurity and gate electrode 102.

Among diffusion layer region 101, both lateral portions that are not opposite to gate electrode 102 function as source/drain regions of the transistor.

FIG. 2 shows cross-sectional views of the RC transistor having an SOI structure shown in FIG. 1, in which (a) is a cross-sectional view taken along line A-A′ of FIG. 1 and (b) is a cross-sectional view taken along line B-B′ of FIG. 1.

As shown in FIG. 2, the RC transistor having an SOI structure whose plan view is shown in FIG. 1 is provided with: semiconductor substrate 100; gate electrode 102; element isolating regions 103; source/drain region N-type impurity diffusion layers 104; gate insulating film 105; and channel layers 111.

Gate electrode 102 is embedded in a trench formed in semiconductor substrate 100. Among gate electrode 102, focusing now on a portion thereof embedded in the trench of semiconductor substrate 100 and which is lower than the surface of semiconductor substrate 100, gate electrode lower portion 102-2 that is the lower part of the embedded portion that is lower than the surface of semiconductor substrate 100 is formed so that the width thereof is wider than that of gate electrode upper portion 102-1 that is the upper part of the embedded portion that is lower than the surface of semiconductor substrate 100. Therefore, the width of the lower part of the trench formed in semiconductor substrate 100 is similarly wider than the upper part thereof.

Element isolating regions 103 are made of silicon oxide film (SiO₂) and are formed by employing STI (shallow trench isolation) formation on semiconductor substrate 100 made of P-type silicon.

As shown in FIG. 2(b), in semiconductor substrate 100, channel layers 111 made of thin-film P-type silicon are formed via gate insulating film 105 at portions opposite to gate electrode upper portion 102-1. Additionally, in channel layers 111, lateral faces that are not opposite to gate electrode 102 are in contact with element isolating regions 103. Furthermore, bottom portions of channel layers 111 are opposite to gate electrode lower portion 102-2 via gate insulating film 105.

Moreover, as shown in FIG. 2(b), gate insulating film 105 is interposed between gate electrode lower portion 102-2 and element isolating regions 103 such that gate electrode lower portion 102-2 and element isolating regions 103 are not in contact with each other. Accordingly, channel layers 111 acquire an SOI structure.

Source/drain region N-type impurity diffusion layers 104 are respectively in direct contact with channel layers 111. When the transistor is in an on-state, the conductivity type of channel layers 111 are inverted into N-type. That causes an on-state current to flow between N-type impurity diffusion layers 104.

According to the technique disclosed in Japanese Patent Laid-Open No. 2007-258660, the electrical properties of an RC transistor are improved by further providing the channel layers of the transistor with an SOI structure.

In the RC transistor having an SOI structure disclosed in Japanese Patent Laid-Open No. 2007-258660, source/drain region N-type impurity diffusion layers 104 are in direct contact with channel layers 111 formed as thin films. As a result, due to the effect of heat applied when manufacturing the transistor, the impurity that exists in source/drain region N-type impurity diffusion layers 104 also diffuses to channel layers 111. Therefore, when the gate length is reduced as semiconductor device miniaturization progresses, there is a problem that the threshold voltage of the transistor decreases due to a short channel effect, thereby making it difficult to control the threshold voltage.

In addition, with an RC transistor whose channel has a thin-film SOI structure, since the SOI structure portion becomes completely depleted when the transistor is driven, a problem exists in that it is difficult to adjust threshold voltage by controlling the impurity concentration within the thin-film channel layer.

Furthermore, there is a problem in that variations are likely to occur in the threshold voltage due to the difficulty of uniformly injecting an impurity into the channel layer on the thin film.

### SUMMARY

A semiconductor device provided with a field-effect transistor,

the field-effect transistor including:

an active region defined by an element isolating region formed on a semiconductor substrate;

a gate electrode provided so as to intersect the active region and having at least a part thereof embedded in a gate trench formed in the semiconductor substrate; and

an SOI structure channel layer formed at the active region so that one lateral face thereof is opposite to a part of the gate electrode embedded in the gate trench and the other lateral face thereof is in contact with a lateral face of the element isolating region, wherein

impurity diffusion layers that function as source/drain regions are disposed at the active region, and the impurity diffusion layers are separated by the gate trench intersecting the active region, and the channel layer is disposed under the impurity diffusion layer, the channel layer being separated from the impurity diffusion layer by a part of the semiconductor substrate which is opposite to a lateral portion of the gate electrode in the gate trench.

In addition, the present invention is a method of manufacturing a semiconductor device provided with a field-effect transistor having a channel layer with an SOI structure, the method including:

forming a first separating trench on a semiconductor substrate so as to leave a portion on which an active region of the field-effect transistor is to be formed;

forming a second separating trench under the first separating trench;

forming an element isolating region by embedding an insulating film in the first separating trench and the second separating trench, and assuming a portion defined by the element isolating region as the active region;

forming an upper part of a gate trench embedding a gate electrode in the semiconductor substrate;

forming a lower part of the gate trench below the upper part of the gate trench, and forming an SOI structure channel layer that is separated from the semiconductor substrate by the lower part of the gate trench;

forming a gate insulating film on an exposed surface of the semiconductor substrate including the gate trench, and forming the gate electrode in the gate trench having the gate insulating film formed on the surface thereof; and

forming an impurity diffusion layer at the active region by injecting an impurity into the semiconductor substrate, wherein

the impurity diffusion layer is formed above the channel layer, the channel layer being separated from the impurity diffusion layer by a part of the semiconductor substrate which is opposite to a lateral portion of the gate electrode in the gate trench.

In the semiconductor device according to the present invention, the impurity diffusion layers that function as source/drain regions are disposed at the active region, and the impurity diffusion layers are separated by the gate trench intersecting the active region, and the channel layer is disposed under the impurity diffusion layer, and the channel layer is separated from the impurity diffusion layer by a part of the semiconductor substrate which is opposite to a lateral portion of the gate electrode in the gate trench.

Therefore, a reduction in the threshold voltage of a transistor due to a short channel effect is prevented to facilitate threshold voltage control.

In addition, fluctuations in the threshold voltage of the transistor can be suppressed.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a plan view of an RC transistor having an SOI structure incorporating a technique for improving electrical properties;

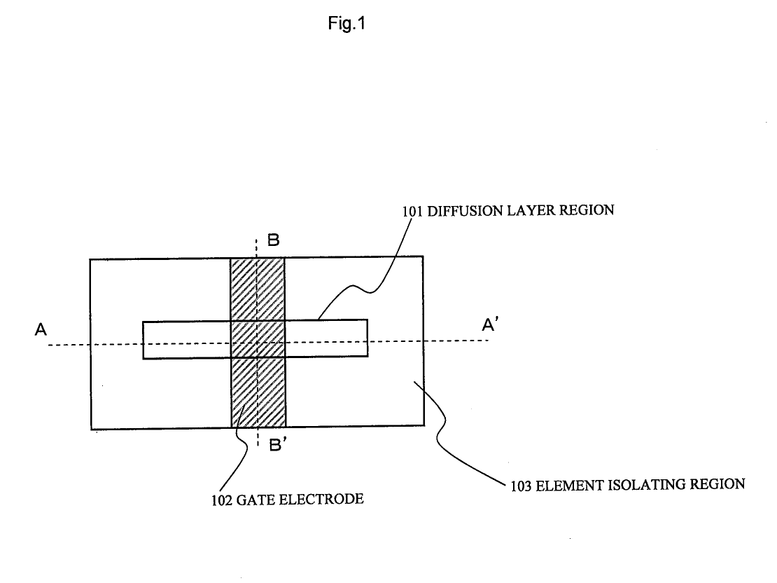

FIG. 2 shows cross-sectional views of the RC transistor having an SOI structure shown in FIG. 1;

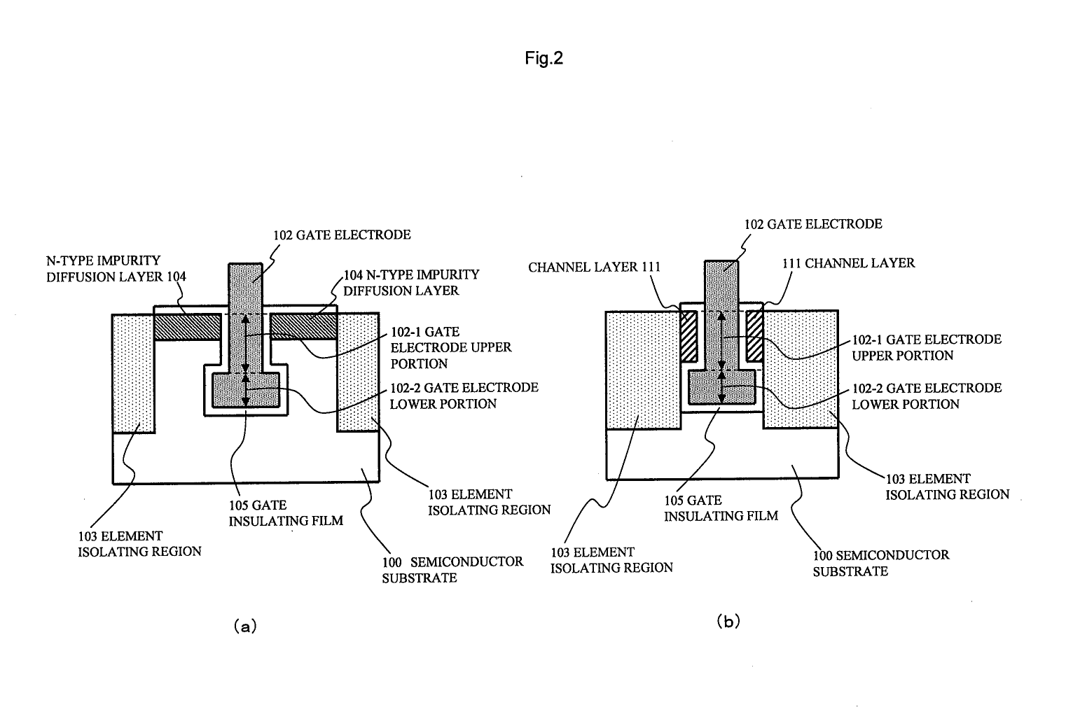

FIG. 3 is a plan view of an RC transistor having an SOI structure according to an embodiment of the present invention;

FIG. 4 shows cross-sectional views of the RC transistor having an SOI structure shown in FIG. 3;

FIG. 5 is a plan view of a semiconductor substrate made of P-type silicon;

FIG. 6 shows cross-sectional views for illustrating a method of manufacturing an RC transistor having an SOI structure according to an embodiment of the present invention;

FIG. 7 shows cross-sectional views for illustrating a method of manufacturing an RC transistor having an SOI structure according to an embodiment of the present invention;

FIG. 8 shows cross-sectional views for illustrating a method of manufacturing an RC transistor having an SOI structure according to an embodiment of the present invention;

FIG. 9 shows cross-sectional views for illustrating a method of manufacturing an RC transistor having an SOI structure according to an embodiment of the present invention;

FIG. 10 shows cross-sectional views for illustrating a method of manufacturing an RC transistor having an SOI structure according to an embodiment of the present invention;

FIG. 11 shows cross-sectional views for illustrating a method of manufacturing an RC transistor having an SOI structure according to an embodiment of the present invention;

FIG. 12 is a plan view of a semiconductor substrate made of P-type silicon and which shows a state after a silicon nitride film has been formed on the semiconductor substrate and after patterning has been performed by dry etching so as to open a region of gate electrode region;

FIG. 13 shows cross-sectional views for illustrating a method of manufacturing an RC transistor having an SOI structure according to an embodiment of the present invention;

FIG. 14 shows cross-sectional views for illustrating a method of manufacturing an RC transistor having an SOI structure according to an embodiment of the present invention;

FIG. 15 shows cross-sectional views for illustrating a method of manufacturing an RC transistor having an SOI structure according to an embodiment of the present invention;

FIG. 16 shows cross-sectional views for illustrating a method of manufacturing an RC transistor having an SOI structure according to an embodiment of the present invention;

FIG. 17 shows cross-sectional views for illustrating a method of manufacturing an RC transistor having an SOI structure according to an embodiment of the present invention;

FIG. 18 shows cross-sectional views for illustrating a method of manufacturing an RC transistor having an SOI structure according to an embodiment of the present invention;

FIG. 19 shows cross-sectional views for illustrating a method of manufacturing an RC transistor having an SOI structure according to an embodiment of the present invention;

FIG. 20 shows cross-sectional views for illustrating a method of manufacturing an RC transistor having an SOI structure according to an embodiment of the present invention;

FIG. 21 is a plan view schematically showing a part of a DRAM memory cell; and

FIG. 22 is a cross-sectional view of the DRAM memory cell shown in FIG. 21.

### DETAILED DESCRIPTION OF THE PREFERRED EMBODIMENTS

The invention will be now described herein with reference to illustrative embodiments. Those skilled in the art will recognize that many alternative embodiments can be accomplished using the teaching of the present invention and that the invention is not limited to the embodiments illustrated for explanatory purpose.

Preferred embodiments of the present invention will now be described with reference to the drawings.

While a case in which an N-channel transistor is used will be described, as will be shown later, a P-channel transistor may also be used.

### First Embodiment

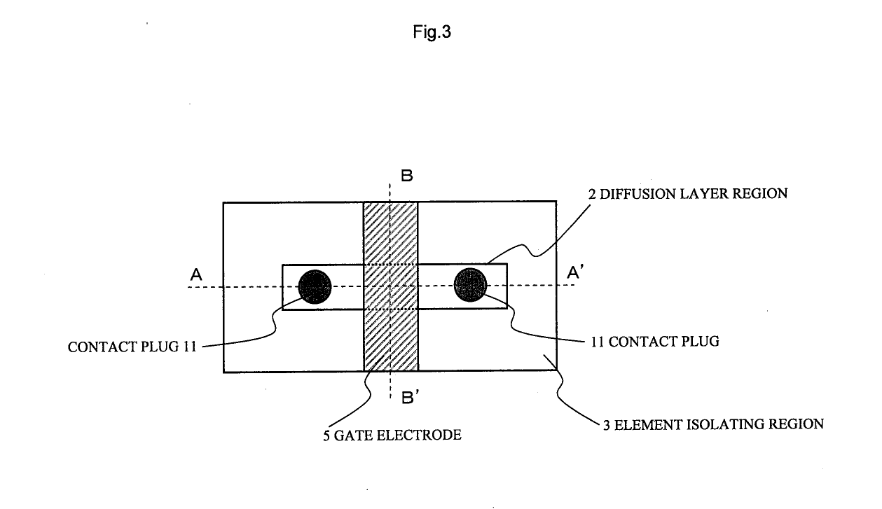

FIG. 3 is a plan view of an RC transistor having an SOI structure according to an embodiment of the present invention. Depictions of an electrode extraction wiring layer and the like have been omitted.

As shown in FIG. 3, an RC transistor having an SOI structure according to the present embodiment is provided with: element isolating regions 3 formed on a semiconductor substrate (not shown) made of silicon or the like; diffusion layer region (active region) 2 defined by element isolating region 3; gate electrode 5; and contact plugs 11.

Among diffusion layer region 2, both lateral portions that are not opposite to gate electrode 5 function as source/drain regions of the transistor.

Contact plugs 11 connect the source/drain regions with a wiring layer (not shown) provided on an upper layer thereof.

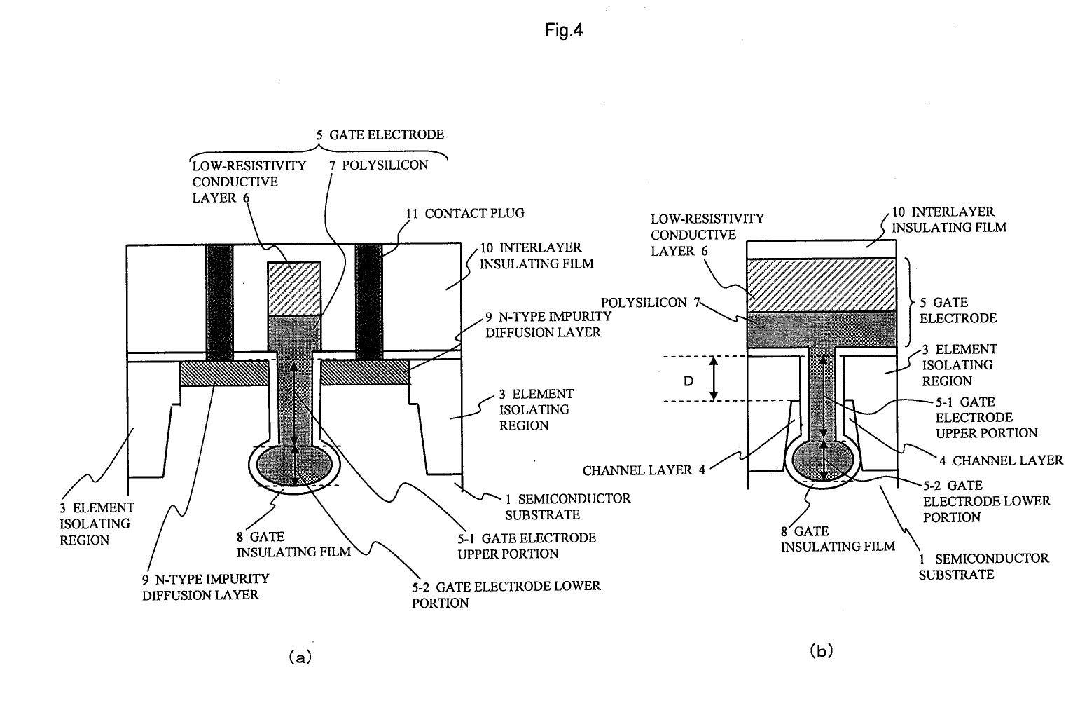

FIG. 4 shows cross-sectional views of the RC transistor having an SOI structure shown in FIG. 3, in which (a) is a cross-sectional view taken along line A-A′ of FIG. 3 and (b) is a cross-sectional view taken along line B-B′ of FIG. 3.

In FIG. 4(a), semiconductor substrate 1 is a semiconductor substrate made of silicon and arranged as a P-type as a result of impurity injection.

Gate electrode 5 is made up of polysilicon (Poly-Si) 7 and low-resistivity conductive layer 6 such as tungsten (W) or the like formed thereabove.

In addition, gate electrode 5 is embedded in a trench formed in semiconductor substrate 1. Among gate electrode 5, focusing now on a portion embedded in the trench of semiconductor substrate 1 and which is lower than the surface of semiconductor substrate 1, gate electrode lower portion 5-2 that is the lower part of the embedded portion that is lower than the surface of semiconductor substrate 1 is formed so that the width thereof is wider than that of gate electrode upper portion 5-1 that is the upper part of the embedded portion that is lower than the surface of semiconductor substrate 1. Therefore, the width of the lower part of the trench formed in semiconductor substrate 1 is similarly wider than the upper part thereof.

Element isolating regions 3 are made of silicon oxide film (SiO2) or the like and are formed by employing STI (shallow trench isolation) formation on semiconductor substrate 1.

N-type impurity diffusion layers 9 are N-type impurity diffusion layers formed by injecting an N-type impurity in diffusion layer region 2 shown in FIG. 3, and function as source/drain regions.

In addition, interlayer insulating film 10 made of silicon oxide film or the like is formed so as to cover gate electrode 5. Conduction between the source/drain regions and a wiring layer (not shown) provided in an upper layer thereof is obtained using contact plugs 11.

As shown in FIG. 4(b), in semiconductor substrate 1, channel layer 4 that is a sidewall-shaped thin film and made of P-type silicon is formed on a lateral face of polysilicon 7 that is a part of gate electrode 5 formed so as to fill the trench.

Channel layer 4 is formed at a position having a depth of D from the surface of semiconductor substrate 1, and is not in direct contact with the source/drain regions constituted by N-type impurity diffusion layers 9 (refer to FIG. 4(a)). In addition, channel layer 4 functions as a channel region through which a current flows when the transistor is in an on-state.

Moreover, as shown in FIG. 4(b), gate insulating film 8 is interposed between a bottom portion of channel layer 4 and gate electrode lower portion 5-2 such that the bottom portion of channel layer 4 and gate electrode lower portion 5-2 are not in contact with each other.

Hereinafter, a detailed description will be given on a method of manufacturing an RC transistor having an SOI structure according to the present embodiment and configured as described above.

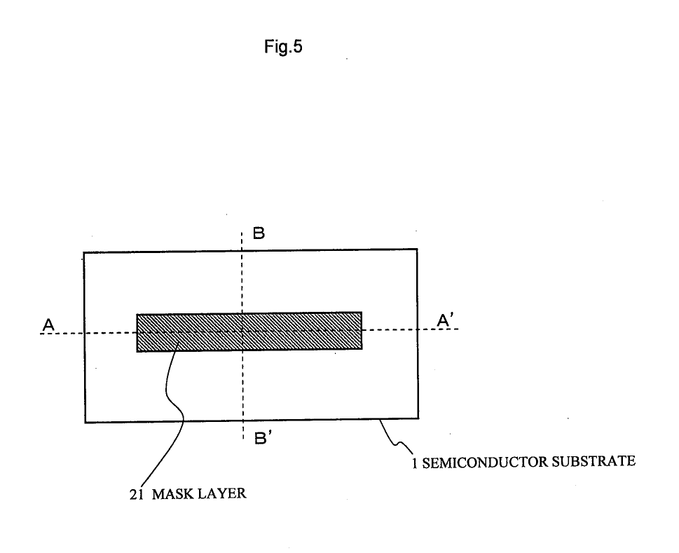

FIG. 5 is a plan view of a semiconductor substrate made of P-type silicon.

First, as shown in FIG. 5, mask layer 21 for forming diffusion layer region 2 (refer to FIG. 3) is formed on semiconductor substrate 1 made of P-type silicon.

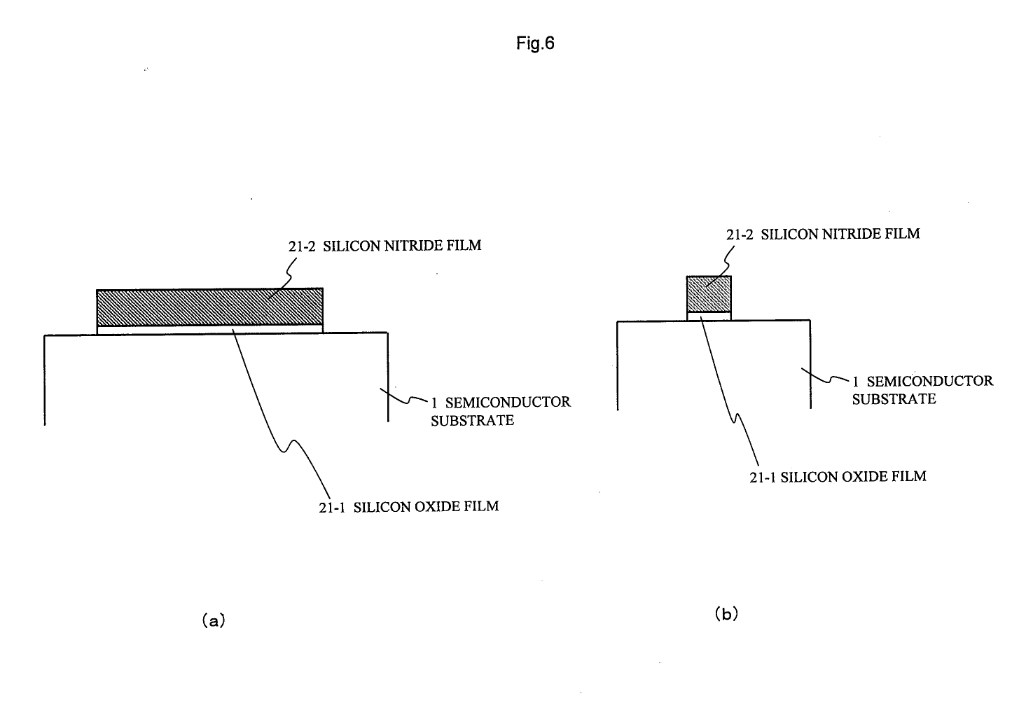

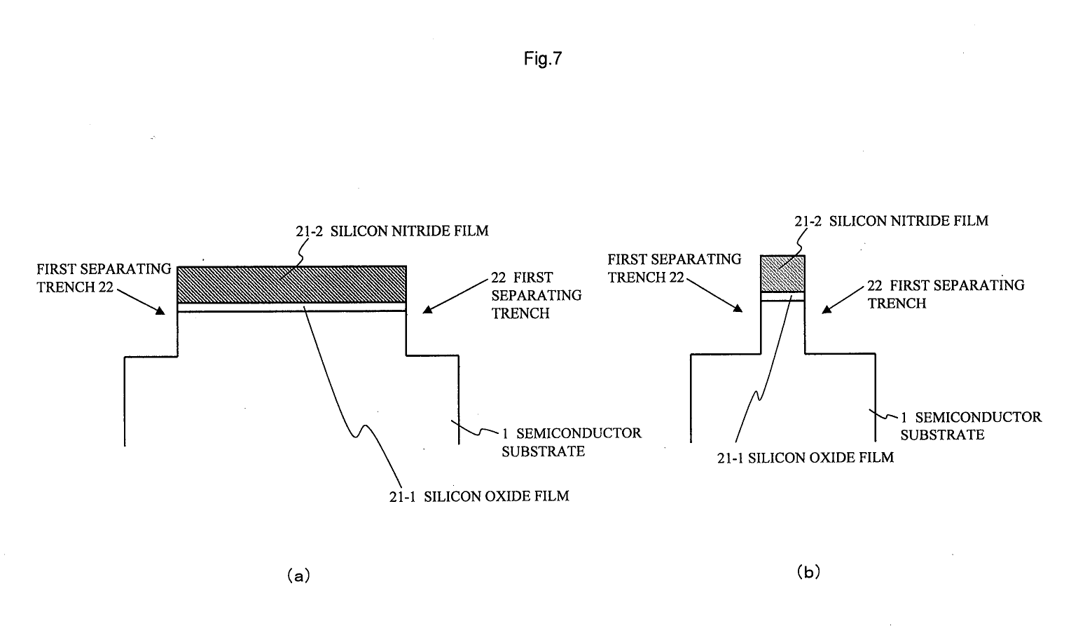

FIG. 6 shows cross-sectional views for illustrating a method of manufacturing an RC transistor having an SOI structure according to an embodiment of the present invention, in which (a) is a cross-sectional view taken along line A-A′ of FIGS. 3 and 5 and (b) is a cross-sectional view taken along line B-B′ of FIGS. 3 and 5. In addition, FIGS. 7 to 11 referred to in the following description respectively show cross-sectional views for illustrating a method of manufacturing an RC transistor having an SOI structure according to an embodiment of the present invention, in which (a) is a cross-sectional view taken along line A-A′ of FIGS. 3 and 5 and (b) is a cross-sectional view taken along line B-B′ of FIGS. 3 and 5.

Next, as shown in FIGS. 6(a) and 6(b), silicon oxide film 21-1 having a thickness of around 9 nm is formed by a thermal oxidation method or the like on semiconductor substrate 1. Subsequently, silicon nitride film (Si₃N₄) 21-2 that is a first mask layer having a thickness of around 120 nm is formed. Mask layer (refer to FIG. 5) is formed by performing patterning using dry etching so as to leave a portion that forms diffusion layer region 2 (refer to FIG. 3). Insofar as patterning is concerned, forming a desired pattern using a photoresist film (not shown) shall suffice.

Next, by performing dry etching on the silicon, as shown in FIGS. 7(a) and 7(b), first separating trench 22 having a depth of around 120 nm is formed in a region other than mask layer 21 (refer to FIG. 5) that is formed by silicon nitride film 21-2 (refer to FIG. 6) of semiconductor substrate 1. As for specific dry etching conditions, for example, dry etching can be performed using a gas combination of chlorine (Cl₂), hydrogen bromide (HBr), oxygen (O₂) and the like under an atmosphere having a pressure of 10 to 50 mTorr. In addition, while an angle (taper angle) of a lateral wall of first separating trench 22 with respect to the vertical direction can be adjusted by varying the flow rate of the etching gas or the like, in this case, the lateral wall of first separating trench 22 is set so as to be approximately vertical (a taper angle of 0 degrees).

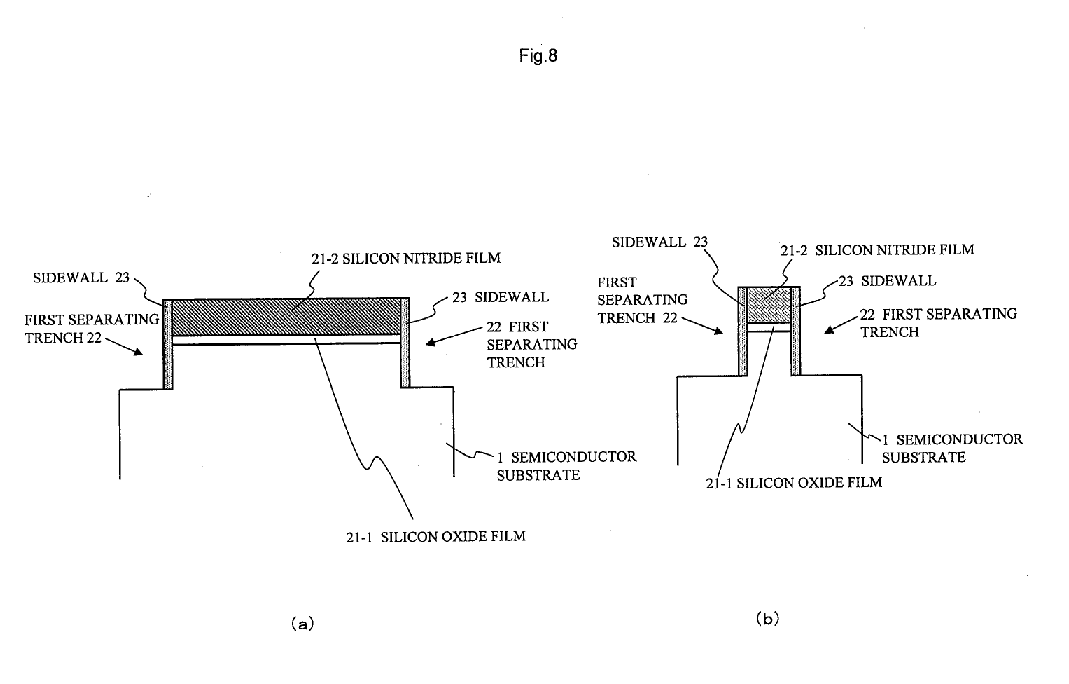

Next, by forming a silicon oxide film having a thickness of around 30 nm by the CVD method and subsequently by performing dry etching on the entire surface without using a mask layer, as shown in FIGS. 8(a) and 8(b), sidewall 23 that is a first sidewall is formed on a side surface of first separating trench 22.

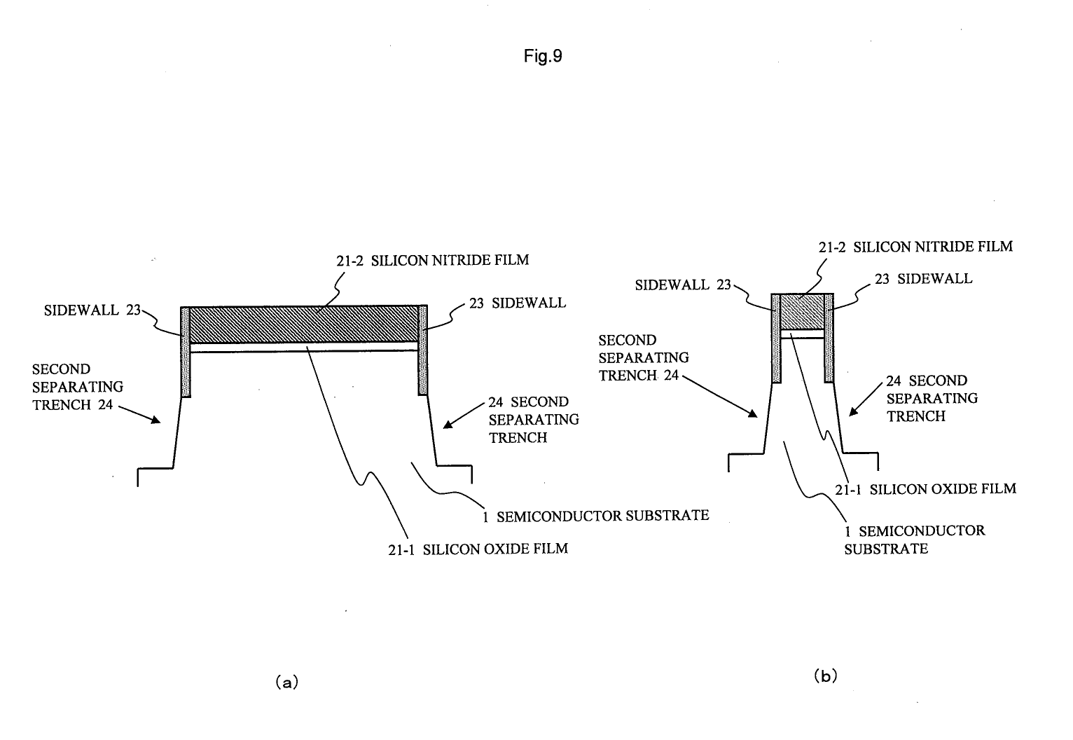

Next, dry etching is once again performed on silicon using mask layer 21 (refer to FIG. 5) formed by silicon nitride film 21-2 (refer to FIGS. 6 to 8) and sidewall 23 (refer to FIG. 8) as masks and, as shown in FIGS. 9(a) and 9(b), second separating trench 24 having a depth of around 120 nm is formed below sidewall 23. An angle formed by a sidewall of second separating trench 24 with respect to the vertical direction can be set according to desired transistor characteristics by varying etching conditions.

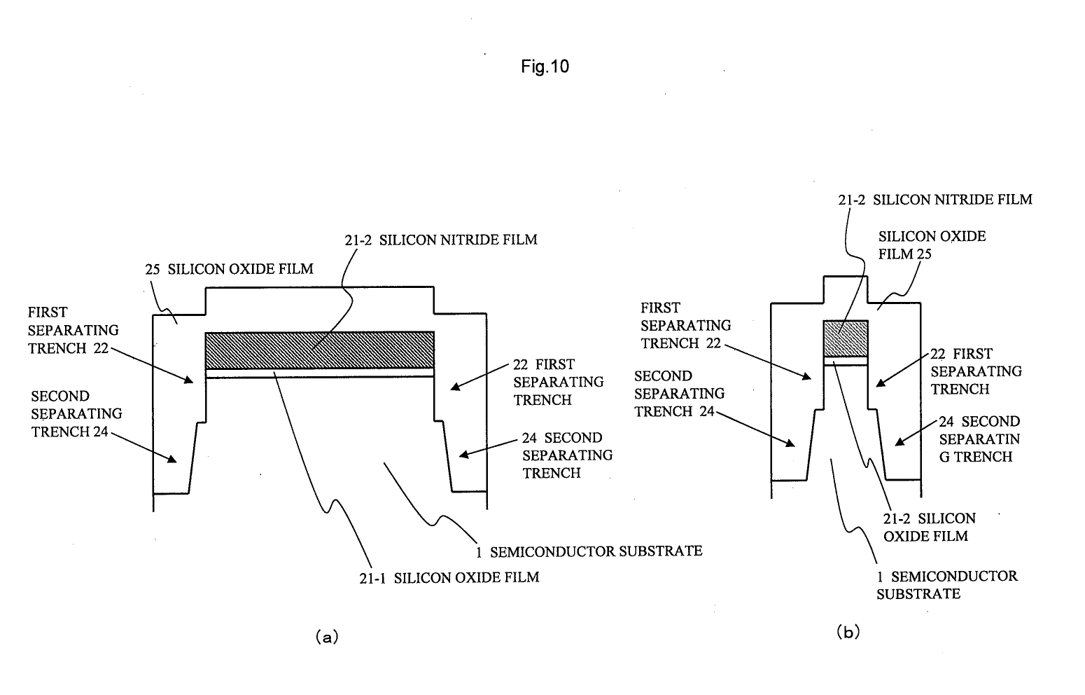

Next, using the CVD method, as shown in FIGS. 10(a) and 10(b), silicon oxide film 25 is formed so as to cover the entire upper surface of semiconductor substrate 1. Since previously-formed sidewall 23 (refer to FIGS. 8 and 9) is formed by the same silicon oxide film, in FIG. 10 and subsequent drawings, a boundary line between silicon oxide film 25 and sidewall 23 will be omitted for the sake of simplicity.

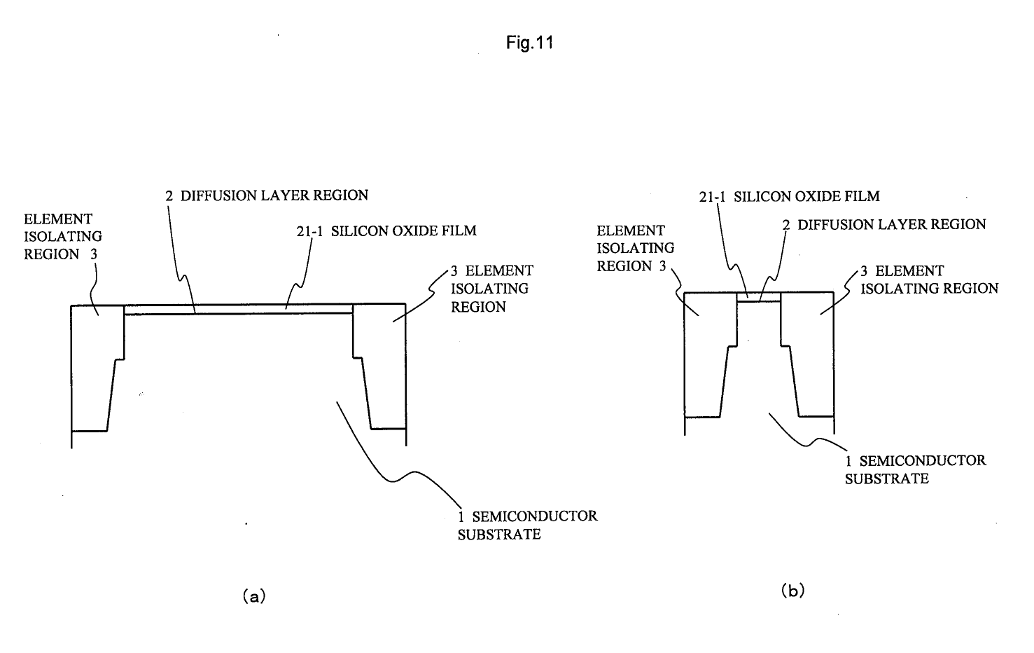

Next, using the CMP (Chemical Mechanical Polishing) method, smoothing of the surface of silicon oxide film 25 (refer to FIG. 10) is performed. Then, as shown in FIGS. 11(a) and 11(b), a remaining portion of mask layer 21 (refer to FIG. 5) formed by silicon nitride film 21-2 (refer to FIGS. 6 to 10) is removed using a chemical such as hot phosphoric acid. Consequently, silicon oxide film remains only at first separating trench 22 and second separating trench 24 (refer to FIG. 10) provided on semiconductor substrate 1, whereby the remaining portions form element isolating regions 3 shown in FIGS. 3 and 4. In addition, the region between element isolating regions 3 of semiconductor substrate 1 becomes diffusion layer region (active region) 2 shown in FIG. 3.

At this point, processing may be performed so as to match the heights of the surface of semiconductor substrate 1 and element isolating regions 3 by first removing the remaining portions of mask layer 21 and then performing wet etching using a chemical such as hydrofluoric acid to remove the silicon oxide film in the vicinity of the surface of element isolating regions 3. Since previously-formed silicon oxide film 21-1 (refer to FIGS. 6 to 10) is also removed when performing such processing, it is sufficient to once again perform thermal oxidation or the like so as to newly form a silicon oxide film having a thickness of around 9 nm at silicon-exposed portions.

Next, a silicon nitride film having a thickness of around 120 nm is formed on semiconductor substrate 1 and patterning is performed by dry etching so as to open the region of gate electrode 5 (refer to FIGS. 3 and 4).

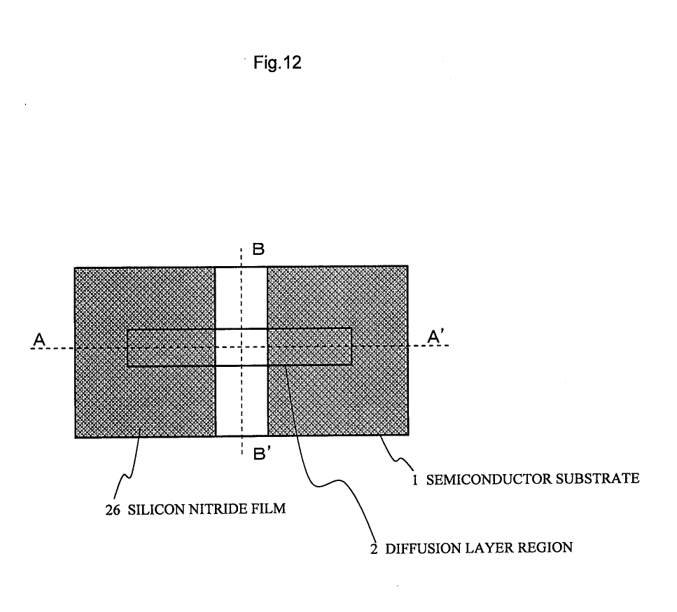

FIG. 12 is a plan view of semiconductor substrate 1 made of P-type silicon and which shows a state after silicon nitride film 26 has been formed and which is a second mask layer on semiconductor substrate 1 and after patterning has been performed by dry etching so as to open the region of gate electrode 5.

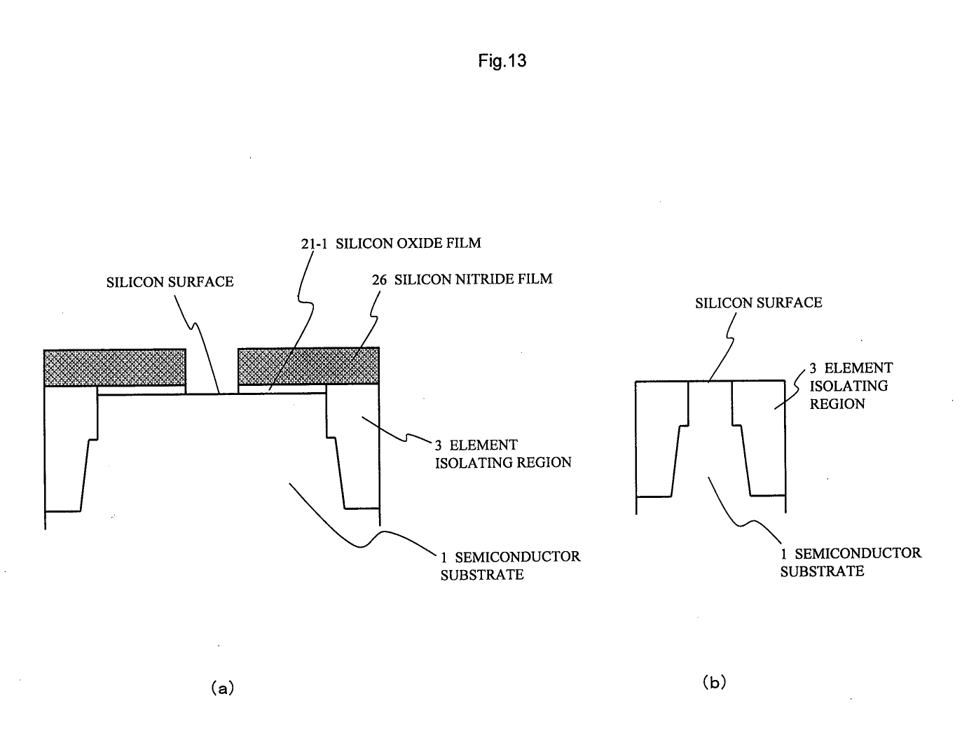

FIG. 13 shows cross-sectional views for illustrating a method of manufacturing an RC transistor having an SOI structure according to an embodiment of the present invention, in which (a) is a cross-sectional view of semiconductor substrate 1 shown in FIG. 12 taken along line A-A′ thereof and (b) is a cross-sectional view of semiconductor substrate 1 shown in FIG. 12 taken along line B-B′ thereof. In addition, FIGS. 13 to 20 referred to in the following description respectively show cross-sectional views for illustrating a method of manufacturing an RC transistor having an SOI structure according to an embodiment of the present invention, in which (a) is a cross-sectional view taken along line A-A′ of FIGS. 3, 5 and 12, and (b) is a cross-sectional view taken along line B-B′ of FIGS. 3, 5 and 12.

As for a specific etching gas to be used when performing dry etching of silicon nitride film 26, for example, a mixed gas consisting of CF₄ (carbon tetrafluoride), CHF₂, and argon can be used. In this case, since previously formed silicon oxide film 21-1 (refer to FIGS. 6 to 11) has a film thickness of only 9 nm and is therefore extremely thin, silicon oxide film 21-1 is removed during the etching of silicon nitride film 26. As a result, the surface of the silicon of semiconductor substrate 1 becomes exposed as shown in FIGS. 13(a) and 13(b).

On the other hand, since the film thickness of the silicon oxide film of element isolating regions 3 is sufficient, only the surface of the silicon oxide film is scraped off to a certain degree and its function as an insulating layer for element isolation remains unaffected.

Next, anisotropic etching of silicon is performed under a condition having a high selectivity with respect to the silicon oxide film that forms silicon nitride film 26 and element isolating regions 3. As for a specific etching gas, for example, a mixed gas consisting of chlorine (Cl₂), hydrogen bromide (HBr), and oxygen (O₂) can be used.

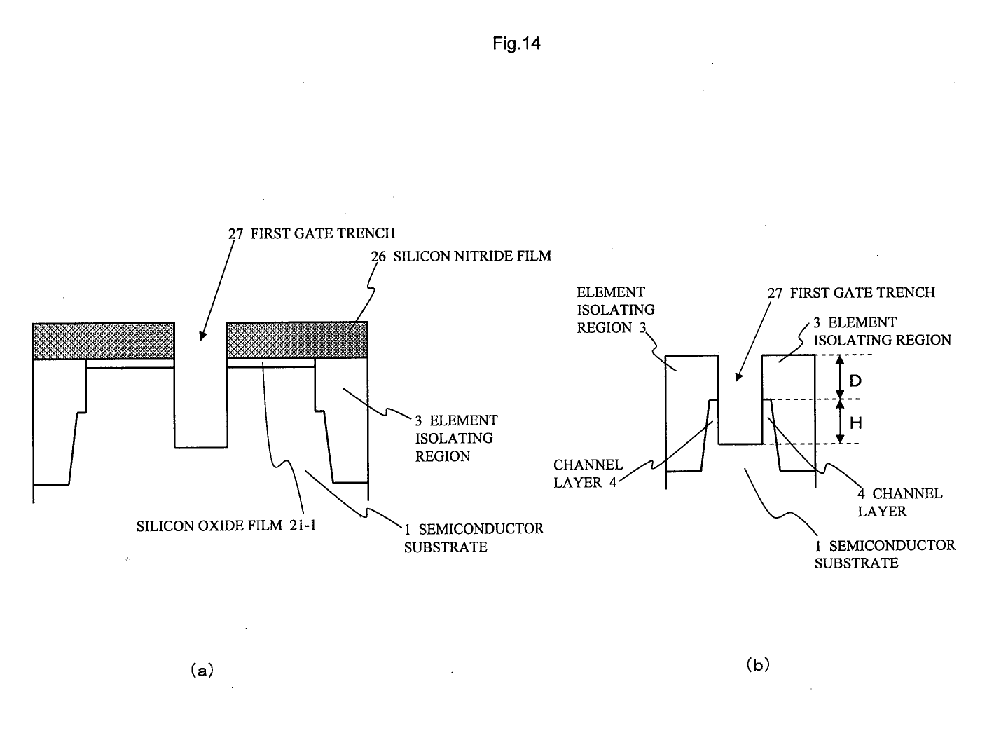

Due to the etching, exposed silicon among the surface of the silicon of semiconductor substrate 1 is removed and first gate trench 27 is formed as shown in FIGS. 14(a) and 14(b). An inner lateral face (silicon face) of first gate trench 27 is arranged such that it has a vertical shape.

In this case, since the silicon oxide film of element isolating regions 3 acts as a mask, thin-film channel layer 4 is formed as shown in FIG. 14(b). Channel layer 4 functions as a channel region of the transistor.

At this point, a depth D of the uppermost portion of channel layer 4 from the surface of semiconductor substrate 1 is arranged so as to be around 80 to 120 nm, and the height H of the uppermost portion of channel layer 4 from the bottom portion of first gate trench 27 is arranged so as to be around 30 to 60 nm.

Since the depth D of the uppermost portion of channel layer 4 from the surface of semiconductor substrate 1 becomes equal to the depth of first separating trench 22 (refer to FIGS. 7 to 10) from the surface of semiconductor substrate 1, adjustment can be realized by adjusting the etching conditions during the formation of first separating trench 22. In addition, the height H of the uppermost portion of channel layer 4 from the bottom portion of first gate trench 27 should be determined according to desired transistor properties.

Furthermore, since the width of channel layer 4 is determined by the film thickness of previously-formed sidewall 23 (refer to FIGS. 8 and 9), adjusting the film thickness when forming sidewall 23 according to desired transistor properties shall suffice.

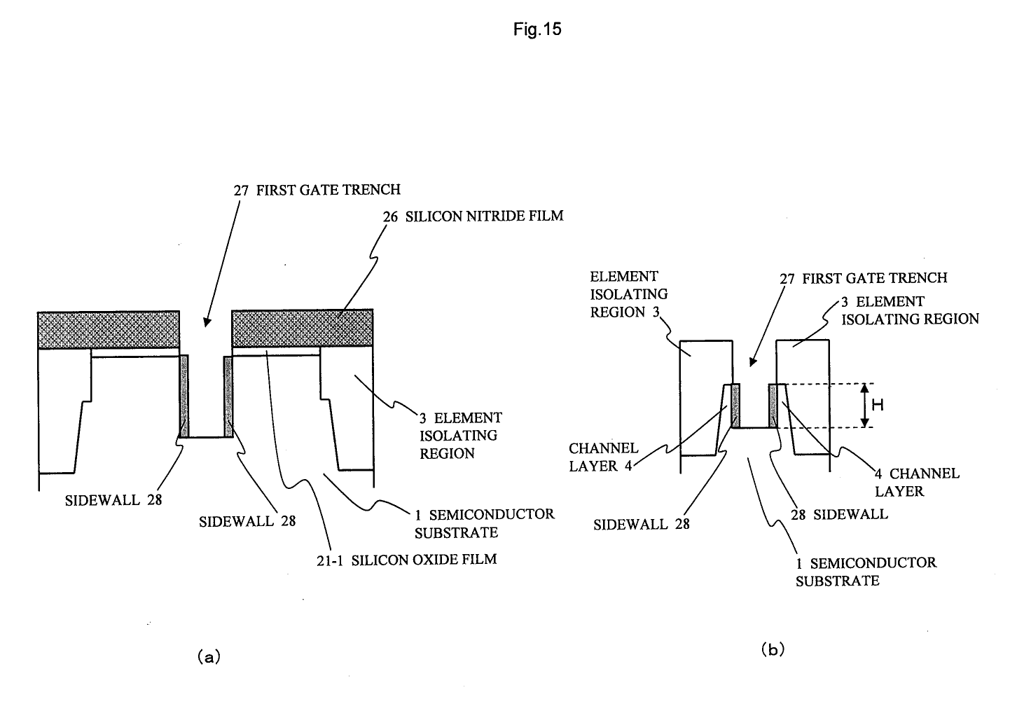

Next, by performing thermal oxidation to form a silicon oxide film having a thickness of around 10 nm on portions at which the silicon surface is exposed and subsequently performing anisotropic dry etching, as shown in FIGS. 15(a) and 15(b), sidewall 28 that is a second sidewall is formed inside first gate trench 27.

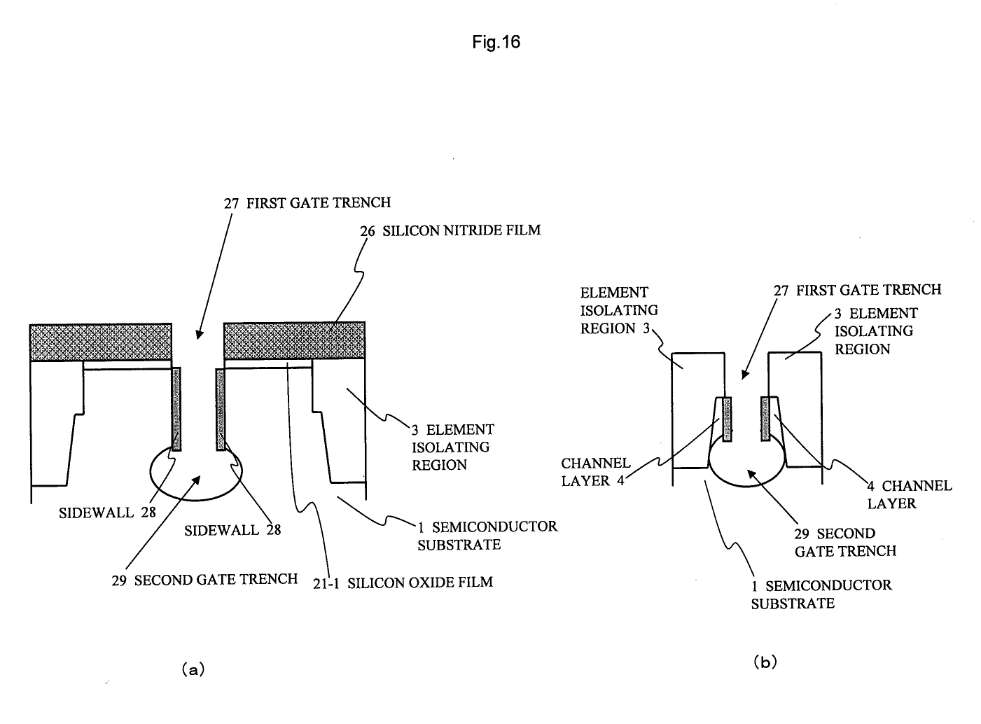

Subsequently, by selectively performing isotropic etching on the silicon using a chemical such as an ammonia-hydrogen peroxide mixture (APM), as shown in FIGS. 16(a) and 16(b), second gate trench 29 is formed below first gate trench 27.

In this case, as shown in FIG. 16(b), the etching time is adjusted so that a region of second gate trench 29 from which silicon is removed by lateral etching reaches the silicon oxide film of element isolating regions 3. By bringing second gate trench 29 into contact with element isolating regions 3, the bottom portion of channel layer 4 is separated from semiconductor substrate 1. Accordingly, channel layer 4 acquires an SOI structure.

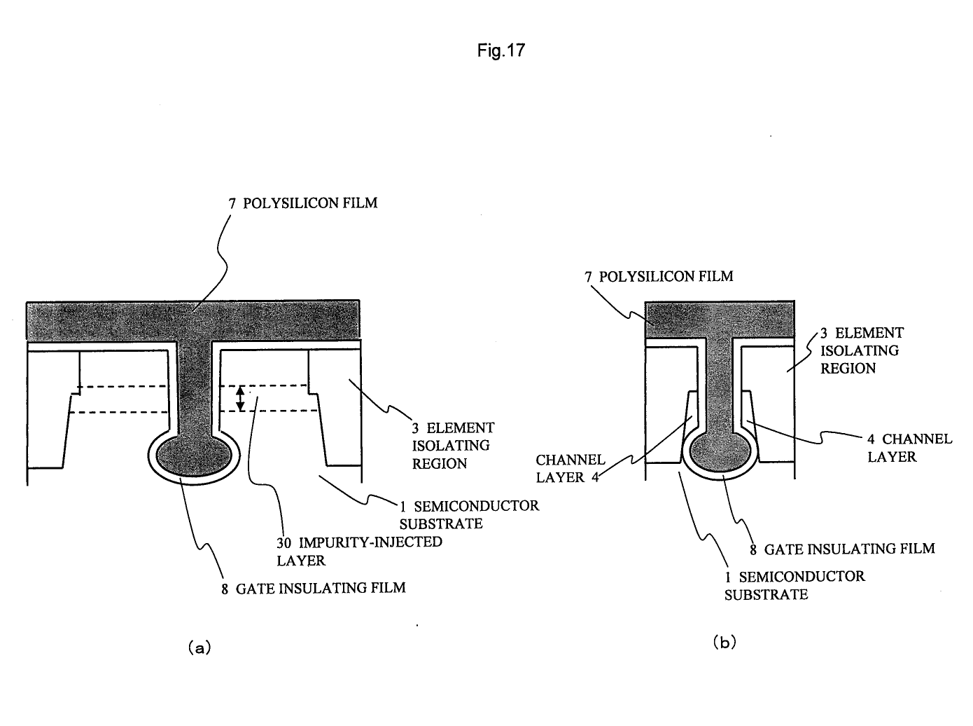

Next, wet etching is performed to remove sidewall 28 (refer to FIGS. 15 and 16), and silicon nitride film 26 (refer to FIGS. 13 to 16) and silicon oxide film 21-1 (refer to FIGS. 6 to 11 and 13 to 16) that are used as masks, to expose the surface of the silicon. Then, as shown in FIGS. 17(a) and 17(b), gate insulating film 8 having a thickness of 3 to 8 nm is formed on the entire surface of the exposed silicon including first gate trench 27 and second gate trench.

As gate insulating film 8, in addition to a silicon oxide film or a laminated film consisting of a silicon nitride film and a silicon oxide film, a High-K film (such as an HfSiON film) having a high-dielectric constant can be used.

Next, using the CVD method, as shown in FIGS. 17(a) and 17(b), polysilicon film 7 having a thickness of around 100 nm and into which phosphorus has been injected as an impurity is formed above gate insulating film 8 so as to fill the insides of first gate trench 27 (refer to FIGS. 14 to 16) and second gate trench 29 (refer to FIG. 16).

Subsequently, ion implantation of boron (B) is performed under an energy of 50 to 80 KeV so as to penetrate polysilicon film 7 to form impurity-injected layer 30 as shown in FIG. 17(a). By adjusting the concentration of boron (ion implantation dose) to be implanted in impurity-injected layer 30, a threshold voltage of the transistor can be adjusted to a desired value.

Moreover, in reality, since the concentration of impurity-injected layer 30 varies continuously, the boundary line with semiconductor substrate 1 is not apparent. In addition, there is no problem even if a part of impurity-injected layer 30 extends reaches into channel layer 4.

Since the boron implanted into element isolating regions 3 is irrelevant to the operations of the transistor, depictions thereof are omitted in FIGS. 17(a) and 17(b). In addition, depiction of impurity-injected layer 30 is omitted from FIG. 17(b).

Next, a low-resistivity conductive layer is formed on polysilicon film 7. As a low-resistivity conductive layer, specifically, a refractory metal film such as tungsten (W), cobalt (Co), and titanium (Ti), a silicide compound containing the same (WSi, CoSi, TiSi), or the like may be used. Alternatively, a nitride of a refractory metal (WN, TiN, and the like) may be used as a barrier film to be laminated with the refractory metal film described above.

Next, patterning is performing using a photoresist film (not shown) as a mask so as to leave only the region of gate electrode 5 shown in FIGS. 3 and 4.

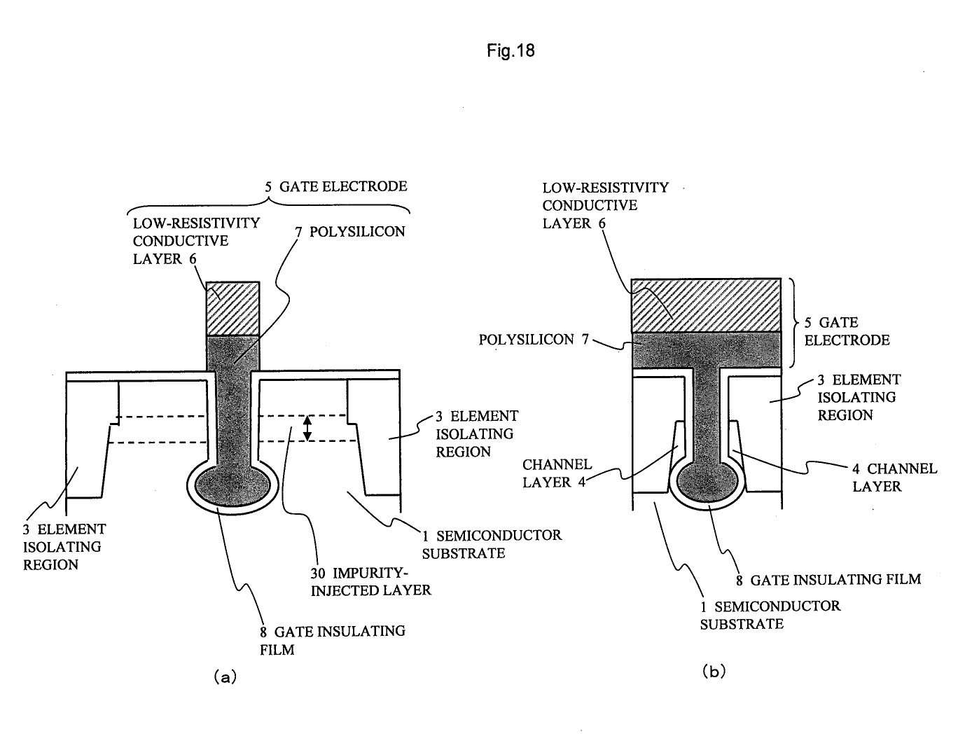

Due to the patterning, as shown in FIGS. 18(a) and 18(b), polysilicon film 7 shown in FIGS. 17(a) and 17(b) becomes a lower portion of gate electrode 5 and low-resistivity conductive layer 6 that is formed on polysilicon film 7 becomes an upper portion of gate electrode 5.

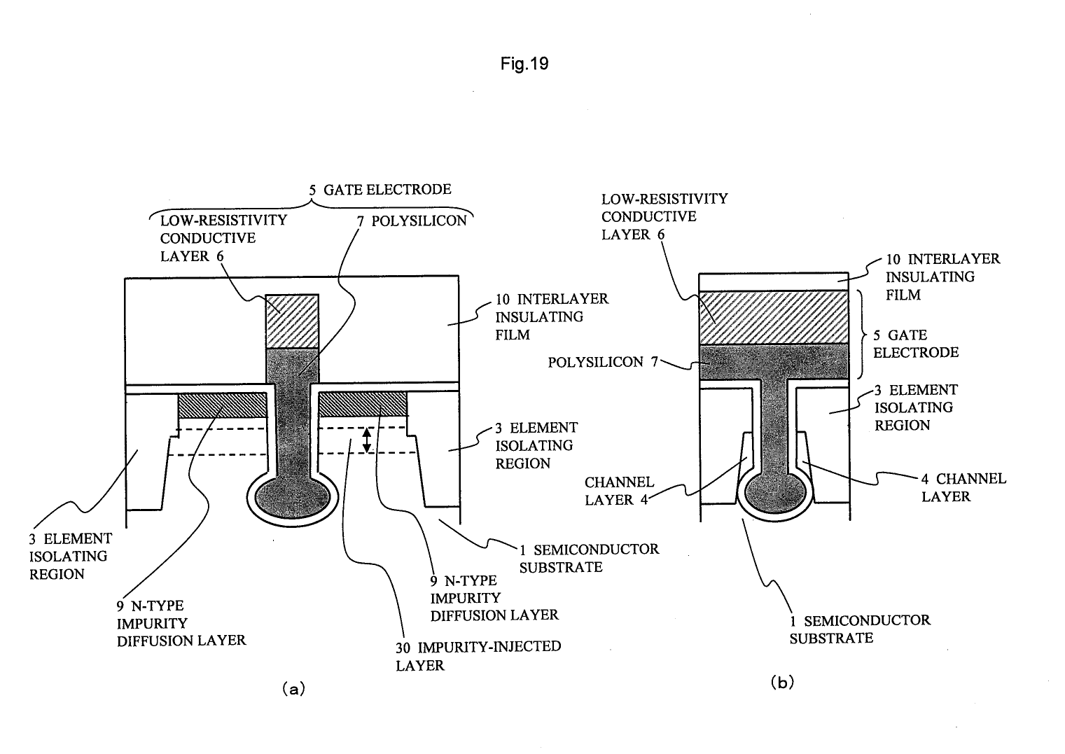

Next, phosphorus (P) is ion-implanted at an energy of 10 to 20 KeV and a dose of 1×10¹² to 1×10¹³ ions/cm², thereby forming N-type impurity diffusion layers 9 such as that shown in FIG. 19(a). The energy of ion implantation is adjusted so that N-type impurity diffusion layers 9 are formed above channel layer 4 (refer to FIGS. 14(b) to 19(b)). N-type impurity diffusion layers 9 function as source/drain regions of the transistor.

Next, as shown in FIGS. 19(a) and 19(b), interlayer insulating film 10 is formed by a silicon oxide film or the like so as to cover gate electrode 5.

Then, contact plugs 11 (refer to FIGS. 3 and 4) to connect source/drain region N-type impurity diffusion layers 9 shown in FIG. 19(a) and a wiring layer (not shown) provided in an upper layer thereof are formed. For gate electrode 5, extraction contact plugs (not shown) should be formed in a similar manner.

Subsequently, by forming a wiring layer (not shown) to be connected to contact plugs 11 using tungsten, aluminum (Al), copper (Cu), or the like, an RC transistor having an SOI structure according to an embodiment of the present invention shown in FIGS. 3 and 4 is formed. Moreover, in FIG. 4, depiction of impurity-injected layer 30 for threshold voltage adjustment is omitted.

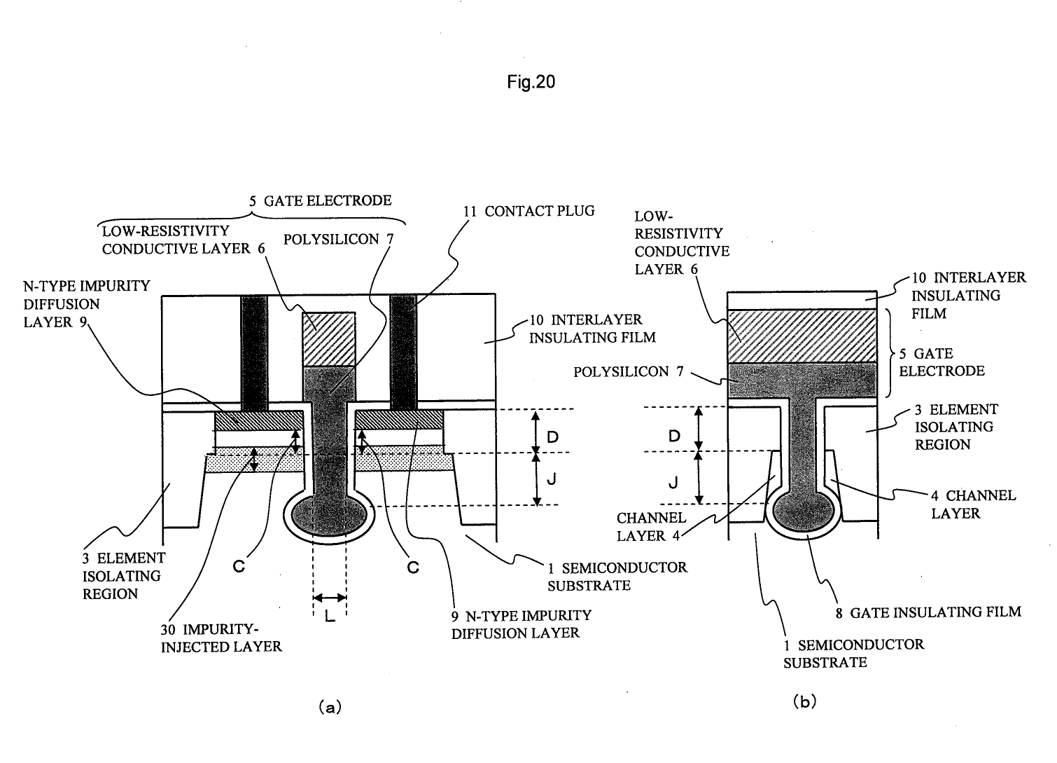

A positional relationship among source/drain region N-type impurity diffusion layers 9, channel layer 4, and impurity-injected layer 30 for adjusting threshold voltage will now be described with reference to FIGS. 20(a) and 20(b).

Channel layer 4 shown in FIG. 20(b) is provided at the position of depth D from the surface of semiconductor substrate 1 so as to have a height of J.

As shown in FIG. 20(a), source/drain region N-type impurity diffusion layers 9 are provided so as to be shallower than the aforementioned depth D from the vicinity of the surface of semiconductor substrate 1. Therefore, the source/drain regions and channel layer 4 are not in direct contact with each other. When the transistor is in an on-state, the conductivity type of a portion that is opposite to gate electrode 5 among a silicon region C between source/drain region N-type impurity diffusion layers 9 and channel layer 4 shown in FIG. 20(b) inverts from P-type to N-type, thereby forming a current path from N-type impurity diffusion layers 9 to channel layer 4. In this case, since silicon region C and impurity-injected layer 30 for adjusting threshold voltage are provided so as to overlap each other, it is now possible to adjust the threshold voltage to enable formation of the current path (the threshold voltage of the transistor) by concentration of impurity-injected layer 30. It should be noted that there is no problem even if impurity-injected layer 30 and N-type impurity diffusion layers 9 are provided so as to be in contact with each other.

As shown, with an RC transistor having an SOI structure according to the present embodiment, since source/drain regions and a channel layer are formed so as to be separated from each other, a short channel effect can be suppressed and a transistor having stable properties can be formed even if gate length L is reduced due to miniaturization.

In addition, since the threshold voltage of the transistor can be adjusted by varying the concentration of an impurity to be injected into the semiconductor substrate between the channel layer and the source/drain regions, there is no need to control the threshold by uniformly injecting an impurity into a thin film portion that forms the channel layer. Therefore, the threshold voltage of the transistor can be more easily set to a desired value and, further, fluctuations in the threshold voltage can be suppressed.

While a case of forming an N-channel transistor has been described for the embodiment presented above, a P-channel transistor can be similarly formed by varying the conductivity type of an impurity. That is, when forming a P-channel transistor, an N-type semiconductor substrate is formed beforehand, whereby an RC transistor is formed in the N-type semiconductor. To form a source/drain region, forming a P-type impurity diffusion layer by implanting boron or boron fluoride (BF₂) shall suffice.

Even in the case of a P-channel transistor, the threshold voltage of the transistor can be adjusted in the same manner as the N-channel transistor described above by controlling the concentration and the conductivity type of an impurity implanted in the silicon region between the source/drain region and the thin-film channel layer.

### Second Embodiment

A case of applying the RC transistor having an SOI structure whose manufacturing method has been described in the first embodiment to a memory cell of a DRAM (Dynamic Random Access Memory) will be described below.

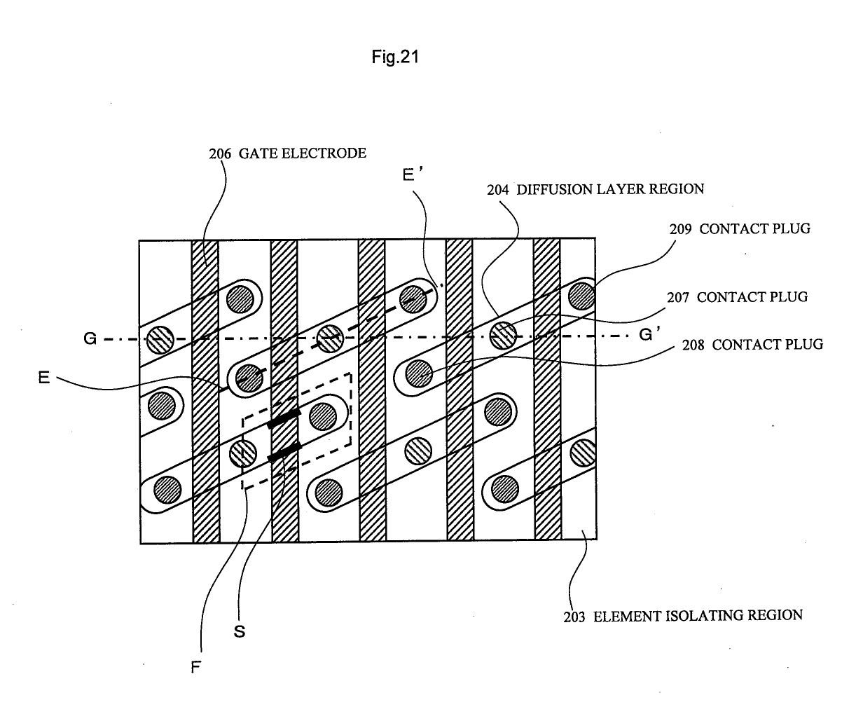

FIG. 21 is a plan view schematically showing a part of a DRAM memory cell that is a memory cell to which is applied a RC transistor having an SOI structure whose manufacturing method has been described in the first embodiment. Hereinafter, for the sake of simplicity, only portions related to the transistor will be described.

As shown in FIG. 21, plurality of diffusion layer regions (active regions) 204 is regularly disposed on a semiconductor substrate (not shown).

Each of a plurality of diffusion layer regions 204 is divided into a plurality of portions by a plurality of element isolating regions 203.

Element isolating regions 203 are formed by the method shown in the first embodiment described above. In addition, a plurality of gate electrodes 206 is disposed so as to intersect diffusion layer regions 204.

Gate electrodes 206 function as word lines of the DRAM. Among diffusion layer regions 204, portions that are not opposite to gate electrodes 206 are ion-implanted with an impurity such as phosphorus to form N-type impurity diffusion layers. The N-type impurity diffusion layers function as source/drain regions of the transistor.

In FIG. 21, a portion enclosed by dashed line F constitutes one RC transistor having an SOI structure, and a trench (not shown) provided in the semiconductor substrate has a unique structure such as that shown in the first embodiment. That is, channel layers 4 (refer to FIG. 4(b) and FIGS. 14(b) to 20(b)) are formed under the portions indicated by bold lines S within dashed line F. The same applies to other diffusion layer regions 204.

In addition, as shown in FIG. 21, contact plug 207 is provided at the center of each diffusion layer region 204 and contacts an N-type impurity diffusion layer on the surface of diffusion layer region 204. Furthermore, contact plugs 208 and 209 are provided at both ends of each diffusion layer region 204 and contact an N-type diffusion layer region on the surface of diffusion layer region 204. While contact plugs 207 to 209 have been given different reference numerals for the sake of description, contact plugs 207 to 209 can be formed simultaneously when actually manufactured.

Moreover, to enable memory cells to be densely disposed, the memory cells shown in FIG. 21 are disposed so that one contact plug 207 is shared by two adjacent transistors.

In addition, in the memory cell manufacturing process shown in FIG. 21, a wiring layer (not shown) in contact with contact plug 207 and perpendicular to gate electrode 206 is formed in the direction indicated by line G-G′. The wiring layer functions as a bit line of the DRAM. Furthermore, capacitor elements (not shown) are respectively connected to contact plugs 208 and 209.

In the RC transistor having an SOI structure whose manufacturing method has been described in the first embodiment, the gate electrode and the diffusion layer region are orthogonal to each other. However, even with a layout in which gate electrode 206 and diffusion layer region 204 obliquely-intersect each other, the RC transistor having an SOI structure whose manufacturing method has been described in the first embodiment is applicable without problems and no deficiencies will arise during the manufacturing process.

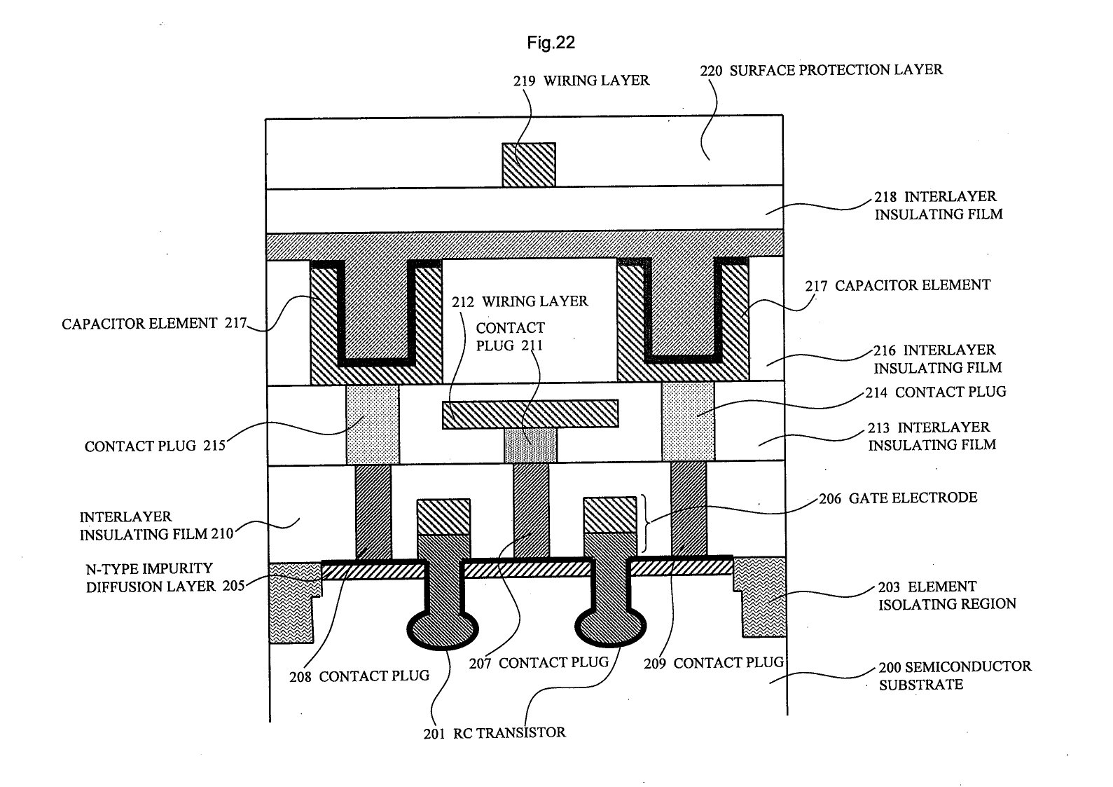

FIG. 22 is a cross-sectional view of the DRAM memory cell depicted in FIG. 21 taken along line E-E′ shown therein.

In the memory cell shown in FIG. 22, RC transistor 201 is configured on top of semiconductor substrate 200 made of P-type silicon. Details of the structure of RC transistor 201 are the same as those described in the first embodiment.

Gate electrodes 206 function as word lines of the DRAM memory cell.

Among diffusion layer regions 204 shown in FIG. 21, N-type impurity diffusion layers 205 are formed on the surface of portions that are not opposite to gate electrodes 206, whereby N-type impurity diffusion layers 205 are in contact with contact plugs 207 to 209.

As for the materials of contact plug 207 to 209, polysilicon injected with phosphorus can be used.

Contact plug 207 is connected via separately provided contact plug 211 to wiring layer 212 that functions as a bit line. Tungsten can be used as a material for wiring layer 212. In addition, contact plugs 208 and 209 are respectively connected via separately provided contact plugs 214 and 215 to capacitor elements 217.

Interlayer insulating film 210 is provided on top of RC transistor 201 and insulates the wiring layer provided in an upper layer thereof.

Interlayer insulating films 213, 216, and 218 provide insulation between the respective wiring layers.

Capacitor elements 217 are formed using known means by interposing an insulating film such as hafnium oxide (HfO) between two electrodes.

Wiring layer 219 is an upper wiring layer formed using aluminum or the like.

By switching RC transistor 201 to an on-state, a memory cell configured as described above is able to judge the presence/absence of a charge accumulated in capacitor elements 217 via the bit line (wiring layer 212), and functions as a DRAM capable of storing information.

As described above, in an RC transistor having an SOI structure according to the present invention, stable properties can be acquired even when gate length L is reduced. Therefore, when using an RC transistor having an SOI structure according to the present invention in a DRAM memory cell, the area of the memory cell can be reduced to enable DRAM with high integration to be easily manufactured.

In addition, since threshold voltage adjustment is readily performed with an RC transistor having an SOI structure according to the present invention, when the RC transistor having an SOI structure according to the present invention is applied to a DRAM memory cell, DRAM provided with desired operational properties can be readily manufactured.

Furthermore, an RC transistor having an SOI structure according to the present invention is usable not only as a DRAM memory cell, but also as other memory cell. For example, by combining the same with a memory element utilizing variations in resistance values in place of a capacitor element, a memory cell for a phase-change memory (PRAM) or a resistive memory (ReRAM) can be formed. Specifically, when forming a memory cell of a phase-change memory, connecting a memory element formed by known means using chalcogenide material (GeSbTe or the like) whose resistance values vary with phase changes to either a source or a drain region of an RC transistor having an SOI structure according to the present invention to form a memory cell shall suffice. In this case, the state (resistance value) of the memory element can be judged by the value of the current that flows when the transistor is switched to an on-state.

Moreover, the present invention is applicable to a general semiconductor device such as a logic product without a memory cell as long as the device uses a MOS transistor.

It is apparent that the present invention is not limited to the above embodiments, but may be modified and changed without departing from the scope and spirit of the invention.

What is claimed is:

1. A semiconductor device provided with a field-effect transistor,
the field-effect transistor comprising:
an active region defined by an element isolating region formed on a semiconductor substrate;
a gate electrode provided so as to intersect the active region and having at least a part thereof embedded in a gate trench formed in the semiconductor substrate; and
an SOI structure channel layer formed at the active region so that one lateral face thereof is opposite to a part of the gate electrode embedded in the gate trench and the other lateral face thereof is in contact with a lateral face of the element isolating region, wherein
impurity diffusion layers that function as source/drain regions are disposed at the active region, and the impurity diffusion layers are separated by the gate trench intersecting the active region, and the channel layer is disposed under the impurity diffusion layer, the channel layer being separated from the impurity diffusion layer by a part of the semiconductor substrate which is opposite to a lateral portion of the gate electrode in the gate trench.

2. The semiconductor device according to claim 1, wherein
an impurity-injected layer controlling a threshold voltage of the field-effect transistor is formed between the channel layer and the impurity diffusion layer.

3. The semiconductor device according to claim 1, wherein
the distance between the surface of the semiconductor substrate and an upper face of the channel layer is within a range of 80 to 120 nm.

4. The semiconductor device according to claim 1, wherein
a lower face of the SOI structure channel layer is opposite to the gate electrode embedded in the gate trench via a gate insulating film.

5. The semiconductor device according to claim 1, further comprising:
a memory element that electrically connects to either a source or a drain region of the field-effect transistor.

6. The semiconductor device according to claim 5, wherein
the memory element is a capacitor, a contact plug being connected between an electrode of the capacitor and an electrode of the field-effect transistor.

7. The semiconductor device according to claim 6, further comprising:
a word line which is connected to the gate electrode of the field-effect transistor; and
a bit line connected to one of the source and drain regions of the field-effect transistor.

8. The semiconductor device according to claim 5, wherein
the memory element includes a material which is capable of changing a resistance to store information.

9. A method of manufacturing a semiconductor device provided with a field-effect transistor having an SOI structure channel layer, the method comprising:
forming a first separating trench on a semiconductor substrate so as to leave a portion on which an active region of the field-effect transistor is to be formed;
forming a second separating trench under the first separating trench;
forming an element isolating region by embedding an insulating film in the first separating trench and the second separating trench, and assuming a portion defined by the element isolating region as the active region;
forming an upper part of a gate trench embedding a gate electrode in the semiconductor substrate;
forming a lower part of the gate trench below the upper part of the gate trench, and forming an SOI structure channel layer that is separated from the semiconductor substrate by the lower part of the gate trench;
forming a gate insulating film on an exposed surface of the semiconductor substrate including the gate trench, and forming the gate electrode in the gate trench having the gate insulating film formed on the surface thereof; and
forming an impurity diffusion layer at the active region by injecting an impurity into the semiconductor substrate, wherein
the impurity diffusion layer is formed above the channel layer, the channel layer being separated from the impurity diffusion layer by a part of the semiconductor substrate which is opposite to a lateral portion of the gate electrode in the gate trench.

10. The method of manufacturing a semiconductor device according to claim 9, wherein
forming the first separating trench comprising:
forming a first mask layer at a portion that forms the active region, and
performing etching of the semiconductor substrate using the first mask layer as a mask.

11. The method of manufacturing a semiconductor device according to claim 10, wherein
forming the second separating trench comprising:
forming a first sidewall on a side surface of the first separating trench, and
performing etching of the semiconductor substrate using the first mask layer and the first sidewall as masks.

12. The method of manufacturing a semiconductor device according to claim 9, wherein
forming the element isolating region and assuming a portion defined by the element isolating region as the active region comprising:
forming a silicon oxide film so as to cover an entire upper face of the semiconductor substrate including the first separating trench and the second separating trench, and
smoothing an upper face of the silicon oxide film.

13. The method of manufacturing a semiconductor device according to claim 9, wherein
forming the upper part of the gate trench comprising:
forming a second mask layer in a region other than the portion at which the gate electrode is formed, and
performing etching of the semiconductor substrate using the second mask layer as a mask.

14. The method of manufacturing a semiconductor device according to claim 9, wherein
forming the lower part of the gate trench and forming the SOI structure channel layer comprising:
forming a second sidewall on an upper inner lateral face of the gate trench, and
performing isotropic etching of the semiconductor substrate using the second sidewall as a mask.

15. The method of manufacturing a semiconductor device according to claim 9, wherein
the first separating trench is formed so that a depth thereof from the surface of the semiconductor substrate is within a range of 80 to 120 nm.

16. The method of manufacturing a semiconductor device according to claim 9, further comprising:
forming an impurity-injected layer controlling a threshold voltage of the field-effect transistor at a region between the channel layer and the impurity diffusion layer.
